(19) United States
(12) Patent Application Publication
(10) Pub. No.: US 2025/0309007 A1
(43) Pub. Date: Oct. 2, 2025

(54) INTEGRATED CIRCUIT (IC) WITH HIGH-VOLTAGE ROBUSTNESS

(71) Applicant: TEXAS INSTRUMENTS INCORPORATED, Dallas, TX (US)

(72) Inventors: Jeffrey Alan West, Dallas, TX (US); Byron Williams, Plano, TX (US); Elizabeth Costner Stewart, Dallas, TX (US)

(21) Appl. No.: 18/619,747

(22) Filed: Mar. 28, 2024

(51) Int. Cl. H01L 21/66; H01L 21/78; H01L 23/00; H01L 23/495

(52) U.S. Cl. CPC H01L 22/32; H01L 21/78; H01L 23/49541; H01L 24/48; H01L 2224/48245; H01L 2924/37001

(57) ABSTRACT

A semiconductor device comprising a semiconductor substrate having a first cut side and an opposite second cut side, a circuit formed in or over the semiconductor substrate between the first and second cut sides, and a first scribelane portion between the circuit and the first cut side and a second scribelane portion between the circuit and the second cut side, the first scribelane portion including conductive scribelane structures, and the second scribelane portion being devoid of conductive scribelane structures.

### FIELD OF THE DISCLOSURE

Disclosed implementations relate generally to the field of semiconductor devices and their fabrication. More particularly, but not exclusively, the disclosed implementations relate to integrated circuits with high-voltage robustness.

### BACKGROUND

Integrated circuit substrates, such as silicon wafers, may contain test structures, electrical probe pads, etc., collectively referred to as scribelane structures, between the integrated circuits disposed on respective semiconductor dies. Dicing operations for separating the integrated circuits may cut through such scribelane structures, potentially leaving remnants in the scribelane portions remaining with the separated dies. In some arrangements, remnants of the scribelane structures may present quality and reliability issues.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device is disclosed, which may comprise, among others, a semiconductor substrate having a first cut side and an opposite second cut side; a circuit formed in or over the semiconductor substrate between the first and second cut sides; and a first scribelane portion between the circuit and the first cut side and a second scribelane portion between the circuit and the second cut side, the first scribelane portion including conductive scribelane structures, and the second scribelane portion being devoid of conductive scribelane structures.

In one example, a method of fabricating an IC is disclosed. The method may comprise, among others, processing a semiconductor wafer in a fabrication flow having a sequence of process stages for creating a plurality of semiconductor dies each containing an instance of the IC, the semiconductor wafer providing a substrate for the IC, the processing including forming scribelanes extending in a first direction, a first subset of the scribelanes including conductive scribelane structures and a second subset of the scribelanes interleaved with the first subset and being devoid of conductive scribelane structures; and singulating the plurality of semiconductor dies in a dicing operation. In some arrangements, the scribelanes of the first subset are located between corresponding first and second adjacent columns of the semiconductor dies, where the semiconductor dies of the first column are identical to and rotated 180° with respect to the semiconductors dies of the second column.

In one example, a packaged IC is disclosed, which may comprise, among others, first package leads on a first side of a device package and second package leads on an opposite second side of the device package; a semiconductor die having a first cut side and an opposite second cut side; a circuit located between the first and second cut sides, the circuit including a first circuit portion and a second circuit portion, the semiconductor die located between the first package leads and the second package leads; a first scribelane portion between the circuit and the first cut side and a second scribelane portion between the circuit and the second cut side, the first scribelane portion including conductive scribelane structures, and the second scribelane portion being devoid of conductive scribelane structures; a lead frame portion over or under the semiconductor die, the lead frame portion extending over the second cut side toward the first cut side and ending over the second circuit portion; bond pads between the first circuit portion and the first cut side; and bond wires connected between the bond pads and the second package leads. In some arrangements, the second circuit portion may comprise Hall effect current sense circuitry exposed to high voltage electric fields and the first circuit portion may comprise interface circuitry operable in low voltage domains.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a baseline semiconductor device comprising a singulated semiconductor die having scribelane portions with remnants of scribelane structures;

FIG. 2A depicts a top view of a semiconductor wafer having a plurality of IC chips or dies where one or more scribelane structures are formed in alternate or interleaved scribelanes according to some examples of the present disclosure;

FIG. 2B depicts a portion of the semiconductor wafer of FIG. 2A in additional detail;

FIG. 3 depicts a semiconductor device comprising a singulated semiconductor die having scribelane portions with remnants of scribelane structures present only in a scribelane portion proximate to a bond pad portion of the semiconductor die according to some examples;

FIG. 4 is a flowchart of a method of fabricating a semiconductor device according to some examples;

FIG. 5 is a flowchart of a method of fabricating a semiconductor device including additional details according to some examples;

FIG. 6 illustrates in a circuit block diagram of an integrated circuit including a Hall current sensing element that may be fabricated using a die floor plan for mitigating high voltage failure risk according to some examples;

FIGS. 7A-7C illustrate different views of a package apparatus for a semiconductor device including a Hall current sensor element where conductive scribelane structures may be present only on a bond pad side of the semiconductor device according to some examples; and

FIG. 8 depicts a partial cross-sectional view of a package including a semiconductor device in an example arrangement of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of high voltage risk abatement in packaged semiconductor devices including sensing circuitry, e.g., Hall effect current sensor elements.

Certain terms and phrases used in the present disclosure are defined and/or described below for purposes of some examples herein. The terms “scribelane” and “scribe lane” may include terms of similar import such as “scribe street”, “scribe line”, or simply “scribe”, etc., and refer to areas on a semiconductor wafer between adjacent semiconductor dies (also referred to as “chips”, “dies”, “device dies”, “integrated circuits (ICs)” or “IC chips”, “semiconductor devices”, or terms of similar import) that are set aside for facilitating physical separation of the dies (i.e., singulation) in a dicing operation.

The term “semiconductor die” as used herein can be a discrete semiconductor device such as a bipolar transistor, a metal oxide semiconductor (MOS) field effect transistor (FET), a few discrete devices such as a pair of power FET switches fabricated together on a single semiconductor die, or a semiconductor die can be an IC with multiple electronic devices such as transistors, capacitors, resistors, etc., in an analog/digital converter (ADC). As such, an example semiconductor die can include passive devices such as resistors, inductors, filters, or can include active devices such as transistors. Further, an example semiconductor die can be an IC with hundreds or thousands of transistors coupled to form a functional circuit, at various levels of integration, for example, a microprocessor, a microcontroller, a memory device, or a system-on-chip device. Semiconductor dies for power applications useful in some arrangements include a discrete power transistor, a gate driver to operate the power transistor, passive components such as capacitors, inductors, and resistors required to implement power circuitry, as well as intelligent high-voltage sensing devices that include protective sensors such as inrush current sensors that add reliability and control to an application system. In some applications, devices may be fabricated of different semiconductor materials, and can be separate semiconductor dies that are mounted in a single device package. In example arrangements, a semiconductor die may include a Hall effect element configured as a current sensor.

The term “semiconductor device package” is used herein. A semiconductor device package may have at least one semiconductor die attached to a supporting structure and electrically coupled to suitable input/output (I/O) terminals, and may comprise a package body that protects and covers the semiconductor die. In some arrangements, multiple semiconductor dies can be packaged together in a semiconductor device package. For example, a power MOSFET semiconductor die and a second semiconductor die (such as a gate driver die or controller device die) can be packaged together to form a single packaged electronic device. Additional components such as passive elements can be included in the packaged electronic device. In some examples, the semiconductor die may be mounted or affixed to a package substrate that provides conductive leads, ribbons, strips, etc., broadly referred to as conductors, where a portion of the conductors may form the terminals for the packaged electronic device. The semiconductor die may be mounted to the package substrate in various orientations relative to each other. In some arrangements, the semiconductor device package may have a package body formed by a thermoset epoxy resin in a molding process, or by the use of epoxies, plastics, or resins that are liquid at room temperature and are subsequently cured. The package body may provide a hermetic package for the packaged electronic device. The package body may be formed in a mold using an encapsulation process, where a portion of the leads of the substrate are not covered during encapsulation, which form or provide a set of exposed terminals for the semiconductor device package for facilitating electrical connectivity with an external system.

The term “package substrate” is used herein. A package substrate is a substrate arranged to receive one or more semiconductor dies and to support the semiconductor die(s) in a completed semiconductor device package. Package substrates may include conductive lead frames, which can be formed from copper, aluminum, stainless steel and alloys such as iron-nickel alloy (e.g., Alloy 42 containing 42% nickel) and other alloys. The lead frames may include die pads for coupling with the semiconductor die, where conductive traces extending from the die pads may be provided for facilitating electrical connections to bond pads on the semiconductor die using wire bonds, ribbon bonds, or other types of conductors. Depending on application, the lead frames may be provided in strips, arrays or other configurations.

The term “spacer dielectric” or “dielectric spacer” is used herein with respect to some examples. A dielectric spacer is an insulating planar structure or a three-dimensional structure that provides electrical isolation between devices mounted to it, e.g., on each side of the spacer. Spacer dielectrics for use in example arrangements include printed circuit board materials, such as flame retardant 4 (FR4) materials, glass reinforced epoxy or fiber substrates, bismaleimide triazine resin (BT) resin substrates, ceramics, other epoxies, resins, polyimide tapes and films. In some arrangements, the dielectric spacer may comprise a laminate of layered dielectric materials.

The term “chamfered” is used herein to describe a surface in some examples. A chamfered surface is a surface that extends from an edge of an object at a slope or an angle. In some arrangements, a portion of a package substrate may have a chamfered surface.

In semiconductor manufacturing, wafer dicing plays an important role in the quality of the product, e.g., singulated IC chips, before packaging. Some mechanical methods for dicing wafers such as, e.g., blade or saw dicing, pulverize the wafer material in the cutting path (known as “dicing street”, “kerf” or “kerf lane”, or terms of similar import) disposed in the scribelane of the semiconductor wafer. Laser dicing may offer several advantages over mechanical dicing operations, especially for IC chips having small form factors (e.g., less than around 1.0 mm²), as it enables significant cost savings by facilitating a reduction both in the total scribe lane widths as well as kerf widths. Regardless of whether mechanical or laser dicing is used, example singulation techniques involve cutting through various structures disposed in the scribelanes, e.g., test structures for monitoring process flow stages, probe pads for electrical characterization, etc., collectively referred to as “scribelane structures”, where some of the structures may be formed using one or more conductive layers such as metal layers. Because dicing operations typically do not entirely remove the scribelane structures during singulation, conductive remnants of a cut scribelane structure may remain in a scribelane portion that is attached to the singulated IC chip, where the conductive remnants may have various form factors including sharp corners, edges, etc. When packaged ICs containing such conductive remnants in the remaining scribelane portions of the separated dies are deployed in high voltage environments, the conductive remnants can function as conductive members disposed in an electromagnetic field, with the sharp corners, edges, etc. experiencing localized force field concentrations that may cause electrical discharge with respect to other conductive elements of the die and/or the package. The propensity for such discharge conditions may be particularly exacerbated where the lead frame of a package substrate is configured to contain a high-voltage sensing element used in current sensing applications, e.g., based on Hall effect.

Examples of the present disclosure recognize the foregoing challenges and provide a die floor plan arrangement configured to (re)locate the scribelane structures only to certain select orientations of the scribelanes associated with a wafer such that scribelane portions associated with a singulated die that are likely to be exposed to high voltage environments are altogether devoid of scribelane structures having conductive components. In such arrangements, therefore, scribelane structures containing conductive components are provided only in scribelanes that are less likely to be exposed to high voltage environments after the dies are singulated and packaged. As will be set forth further below, selective (re)location of scribelane structures in a wafer may be accomplished by suitable topological/spatial (re)orientation of the dies in a layout based on identifying, determining or otherwise recognizing that certain portions of the circuitry on the die may be exposed to higher voltages than the remaining portions and appropriately (re)arranging the location of the dies in the floor plan relative to one another so that the circuit portions of adjacent dies less likely to be exposed to high voltage environments share a scribelane that can be populated with appropriate scribelane structures. Conversely, and as a consequence, the circuit portions of adjacent dies likely to be exposed to high voltage environments are positioned to share a scribelane that is not used for fabricating scribelane structures. Because there may be scribelanes that are devoid of scribelane structures, especially structures including shear-inducing metallic components, the potential for crack generation and/or propagation during dicing that negatively impacts yields (e.g., die per wafer or DPW) may be reduced as an additional benefit in some examples. Whereas described examples may be expected to reduce the risk of electrical discharge events in packaged ICs (e.g., shorting, arcing, etc.) as well as provide increased separation yields, no particular result is a requirement unless explicitly recited in a particular claim.

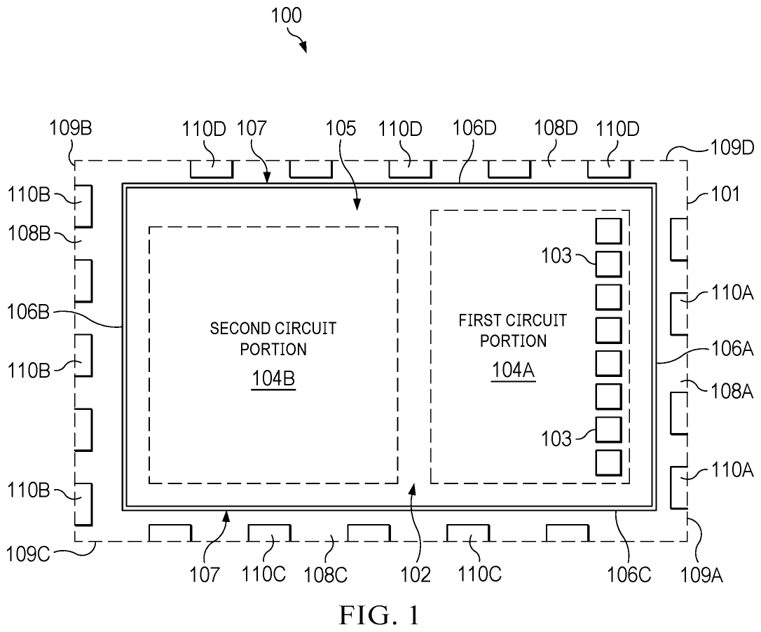

Turning to the drawing Figures, FIG. 1 depicts a singulated semiconductor die 100 representing a baseline semiconductor device where remnants of scribelane structures may be extant in each scribelane portion of the device. As illustrated, the semiconductor device or die 100 may comprise a device region 102, also referred to as an active die region or circuit region, surrounded by a scribe seal or guard ring 107, where the device region 102 may include one or more circuit portions 104A, 104B, collectively referred to as a circuit or circuitry 105, formed in or over a semiconductor substrate 101. For purposes of the present disclosure, the device region 102 may be a portion of the semiconductor substrate 101 of the semiconductor die 100 in which one or more microelectronic components such as transistors, resistors, diodes, capacitors, etc., are fabricated, e.g., as discrete components and/or as an IC. Whereas the scribe seal 107 may completely surround the device region 102 in some implementations, it is not a necessary requirement. For example, a scribe seal may be comprised of one or more segmented portions disposed on each side of the device region 102 depending on implementation.

The semiconductor substrate 101 may have multiple cut sides due to singulation, e.g., a first cut side 109A, an opposite second cut side 109B, a third cut side 109C and a fourth cut side 109D opposite to the third cut side 109C, where the cut sides 109A-109D represent boundaries or edges of scribelane portions remaining after the dicing operation that surround the scribe seal 107 and the device region 102. In general, the first and second cut sides 109A, 109B are roughly parallel to each other and oriented in one direction (e.g., a first direction), and the third and fourth cut sides 109C, 109D are roughly parallel to each other and oriented in a second direction such as orthogonal to the first direction, as is known in the art. In an example arrangement, the scribe seal 107 may comprise multiple sides, e.g., a first scribe seal side 106A, a second scribe seal side 106B, a third scribe seal side 106C and a fourth scribe seal side 106D, where each scribe seal side separates a side of the device region 102 from a corresponding scribelane portion remaining after the dicing operation. A first scribelane portion 108A extends from the scribe seal side 106A to the first cut side 109A, a second scribelane portion 108B extends from the scribe seal side 106B to the second cut side 109B, a third scribelane portion 108C extends from the scribe seal side 106C to the third cut side 109C, and a fourth scribelane portion 108D extends from the scribe seal side 106D to the fourth cut side 109D.

Each scribelane portion 108A/D may include remnants of one or more scribelane structures comprising dielectric and/or metal components, e.g., electrical test pad structures, photo alignment marks, alignment measurement boxes, chemical mechanical polishing (CMP) test structures, critical dimension (CD) control marks, as well as inline monitoring structures provided for characterizing parameters such as film thickness and planarity, optical properties (e.g., refractive index, extinction coefficient, etc.), surface behavior, interface behavior, alloy concentrations and their uniformities across surfaces, and the like. By way of illustration, the first scribelane portion 108A may contain scribelane structure remnants or portions 110A, the second scribelane portion 108B may contain scribelane structure remnants or portions 110B, the third scribelane portion 108C may contain scribelane structure remnants or portions 110C, and the fourth scribelane portion 108D may contain scribelane structure remnants or portions 110D.

In some examples, the circuitry 105 of die 100 may be configured to include one or more bond pads 103 only on one side of the device region 102, which may be referred to as a bond pad side in some arrangements. In some examples, the bond pads 103 may be provided as part of or otherwise associated with a particular portion of the circuitry 105, e.g., the first circuit portion 104A, that may be configured as an interface circuit operable to interface with an external circuit or system disposed in a low voltage domain. In some examples, remaining portions of the circuitry 105, e.g., the second circuit portion 104B, may include current sensing circuitry based on Hall effect, where the sensing circuitry may be exposed to electric fields generated by conductors in a high voltage domain. As noted previously, remnants of the scribelane structures having metallic components in scribelane portions proximate to such circuit portions may cause undesirable electric discharge conditions when exposed to electric fields in certain application scenarios.

In some baseline flows, a protective overcoat (PO) formed over a semiconductor process wafer from which the semiconductor die 100 is singulated may be patterned in a suitable PO removal (POR) process in order to mitigate or reduce cutting path meandering and/or crack formation/propagation during dicing operations. For example, one or more slots having a predetermined width and depth may be formed in the PO layer that coincide or align with the scribelane of the semiconductor process wafer and/or extend over the scribe seal of the semiconductor die 100 may be formed in some arrangements. Depending on implementation, a PO dielectric layer may have a total thickness of several tens or hundreds nanometers (nm) to several microns (μm) that may include one or more layers or sublayers of insulator materials such as, e.g., silicon nitride, silicon oxide, oxynitride, polyimide, etc. that may be deposited as part of a back end of line (BEOL) process flow. In general, IC chips designed to operate with higher voltages may require thicker POs. In one implementation, a PO layer may be planarized before slot patterning in order to better align the PO slots with the scribelane grid of the semiconductor process wafer. Depending on implementation, POR slots may be continuous or discontinuous, and may span across the entire scribe lane or formed in only select portions thereof. In some arrangements, a POR slot may have a width of, e.g., about 1 μm-20 μm, and may have a depth of about several nanometers to a few microns depending on implementation. In some arrangements, POR slots may be formed concurrently with the formation of pad/contact openings in a process flow. Accordingly, the scribe seal 107 of the baseline semiconductor die 100 shown in FIG. 1 may be exposed in select POR areas, which may further increase the risk of electric discharge in some applications.

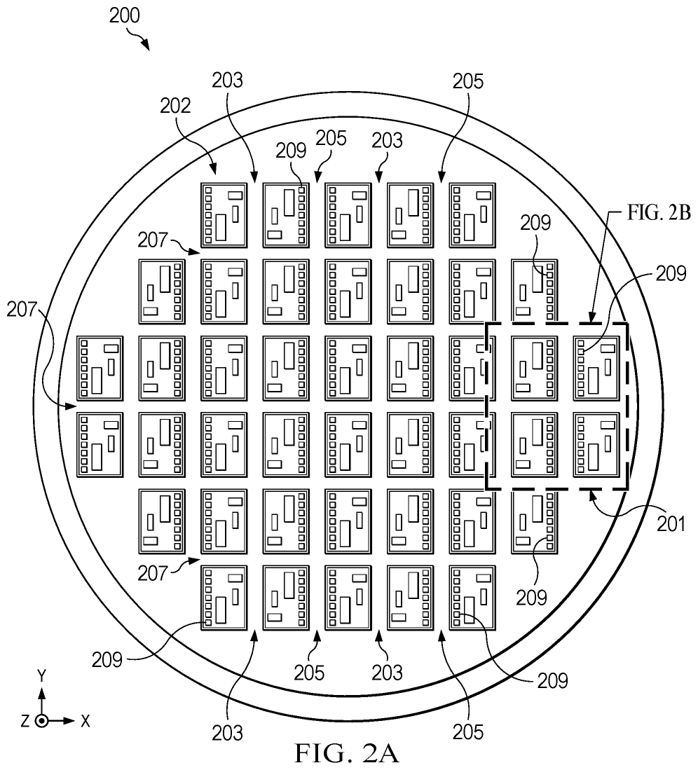

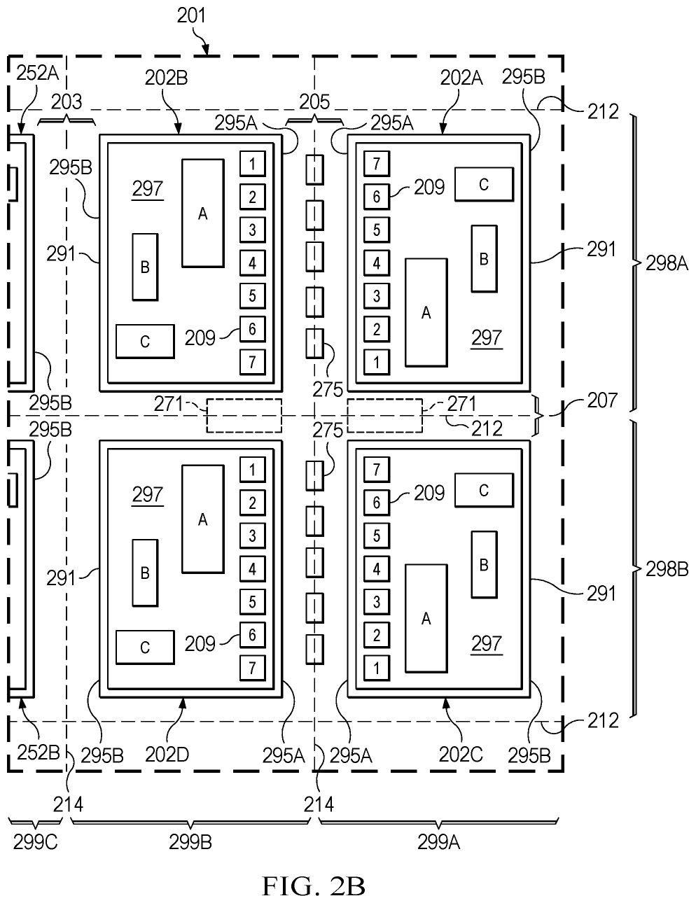

FIG. 2A depicts a top plan view of a semiconductor wafer 200 having a plurality of IC chips or dies 202 formed in or over a semiconductor substrate in a grid-like pattern, where scribelane structures are formed only in a select subset of scribelanes in order to eliminate, reduce or otherwise mitigate the risk of exposure of scribelane structural remnants to electric fields according to some examples of the present disclosure. For purposes of the present disclosure, semiconductor wafer 200 may also be referred to as a semiconductor process wafer or simply a process wafer, handle wafer or wafer in some examples. By way of illustration, representative IC dies 202A-202D are shown with further detail as an array in a thumbnail portion 201 depicted in FIG. 2B, where each IC die separated from other dies by one or more scribelanes formed in the wafer 200 that extend in a first direction, e.g., along Y-axis (referred to as a vertical direction in some examples), and in a second direction, e.g., along X-axis (referred to as a horizontal direction in some examples), that may be orthogonal to the first direction. In some examples, the scribelanes extending in the first direction may comprise a first subset of scribelanes 205 including scribelane structures 275 (e.g., scribelane structures having conductive metal components), which may be interleaved with a second subset of scribelanes 203 not including scribelane structures, e.g., devoid of scribelane structures with conductive metal components. In some examples, the second subset of scribelanes 203 may include scribelane structures that do not have any metallic components (not specifically shown in this Figure). Similar to the second subset of scribelanes 203, the scribelanes extending in the second direction orthogonal to the first direction, e.g., scribelanes 207, may be completely devoid of scribelane structures altogether, or at least devoid of conductive scribelane structures. In other words, the scribelanes 207 extending in the second direction may include scribelane structures that do not have metallic components in some examples (not specifically shown in this Figure).

As depicted in the thumbnail array portion 201, the representative semiconductor dies 202A-D each comprise a device region 297 surrounded by a scribe seal 291, the device region 297 including circuit portions A, B and C positioned relative to each other according to a floor plan. Each die 202A-D includes a first side 295A (referred to as a bond pad side) that is provided with a plurality of bond pads 209 and an opposing second side 295B (referred to as a non-bond-pad side) having no bond pads. The semiconductor dies 202A-D may be organized into rows and columns, e.g., adjacent rows 298A, 298B separated by the scribelane 207, and adjacent columns 299A, 299B separated by the scribelane 205. In the examples herein, the layout of the IC dies on a wafer (e.g., wafer 200) may be (re)oriented by (re)arranging the tapeout of the reticles (used for step-and-print photolithography layers) or the masks (containing the entire pattern of a single layer of a full wafer) deployed in the fabrication of the dies 202 according to a die floor plan in order to achieve suitable topological configuration for aligning the bond pad sides of adjacent semiconductor devices relative to each other along a particular direction. By virtue of suitable arrangement in the mask/reticle layout used for fabricating the wafer 200, the semiconductor dies 202A, 202C of the column 299A may be oriented relative to the corresponding semiconductor dies 202B, 202D, respectively, of the column 299B such that the respective bond pad sides 295A of the semiconductor dies 202A and 202B face each other and the respective bond pad sides 295A of the semiconductor dies 202C and 202D face each other. In some arrangements, the semiconductor dies 202A and 202C of the column 299A may be rotated 180° with respect to the semiconductor dies 202B and 202D of the column 299B, respectively, in the mask/reticle layout to achieve the desired orientation of the bond pad sides of the semiconductor dies in one column relative to the bond pad sides of the semiconductor dies of the corresponding adjacent column. In some additional and/or alternative arrangements, the semiconductor dies of a column may be provided as mirror images of the corresponding semiconductor dies of an adjacent column in order to achieve the desired orientation of the bond pad sides, where the I/O circuitry of a mirror imaged die may be appropriately reconfigured with respect to the bond pads.

In the examples herein, the bond pad sides 295A of the semiconductor dies 202 are configured to be exposed to low voltage environments. Accordingly, the scribelane 205 between the columns 299A and 299B may be provided with the scribelane structures 275 in a representative example as shown in FIGS. 2A/2B. Because the bond pad sides 295A of the semiconductor dies of a pair of adjacent columns are oriented to face each other, the non-bond-pad sides 295B of the semiconductor dies of a pair of adjacent columns separated by an interleaving scribelane 203, e.g., column 299B and column 299C (shown with partially depicted dies 252A, 252B in the array portion 201) also face each other. In the examples herein, the non-bond-pad sides 295B of the semiconductor dies 202 may be exposed to high voltage environments. Accordingly, the interleaving scribelane 203 between the columns 299B and 299C may be provided as a scribelane without any scribelane structures or at least without scribelane structures having metallic components as noted previously. In the examples herein, therefore, a scribelane 205 containing metallic/conductive scribelane structures may alternate with a scribelane 203 containing no (or non-conductive) scribelane structures in a repeating manner across the entire wafer 200 thus giving rise to an interleaved arrangement of the first subset of scribelanes 205 and the second subset of scribelanes 203 shown in the top plan view of the wafer 200, where the bond pad sides 295A of an adjacent pair of columns of the semiconductor dies 202 face each other and the non-bond-pad sides 295B of an adjacent pair of columns of the semiconductor dies 202 face each other.

In some examples, the scribelanes 207 extending in the second direction and disposed between adjacent rows of semiconductor dies, e.g., rows 298A and 298B, may also be provided as scribelanes completely devoid of scribelane structures, although it is not a requirement. In some examples, the scribelanes 207 may include non-conductive scribelane structures as previously noted. In some examples, select portions of the scribelanes 207 proximate to the bond pad sides 295A, e.g., portions 271, that have a low risk of exposure to high voltage environments may be provided with metallic/conductive scribelane structures (not shown in this Figure).

Die separation may be accomplished by effectuating cutting paths 212, 214 through the horizontal scribelanes 207 and the interleaved vertical scribelanes 203/205, respectively, of the wafer 200. Because the orientation of the semiconductor dies of a column is different than as the orientation of the semiconductor dies of an adjacent column (e.g., rotated by 180° clockwise or counterclockwise), a pick-and-place mechanism of a packaging tool used for packaging the singulated dies may be appropriately configured to account for the orientational difference between the columns of semiconductor dies during packaging.

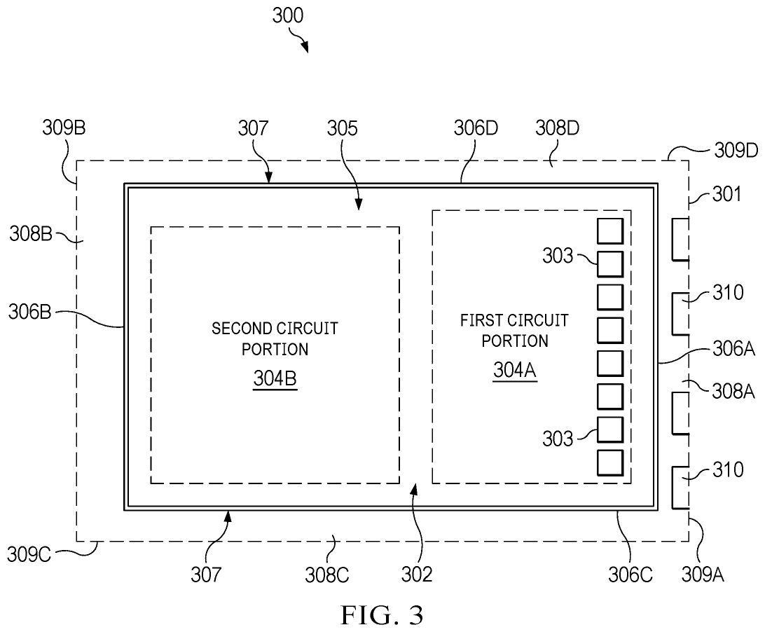

FIG. 3 depicts a singulated semiconductor die 300 representing a semiconductor device where remnants of scribelane structures may be present only in a scribelane portion having a select orientation and proximate to a bond pad side of the device according to some examples herein. The semiconductor device or die 300 may comprise a device region 302, also referred to as an active die region or circuit region similar to the example shown in FIG. 1, which may be surrounded by a scribe seal or guard ring 307, where the device region 302 may include one or more circuit portions 304A, 304B, collectively referred to as a circuit or circuitry 305, formed in or over a semiconductor substrate 301. Whereas the scribe seal 307 may completely surround the device region 302 in some implementations, it is not a necessary requirement, as previously noted.

In an example arrangement, the scribe seal 307 may comprise multiple sides, e.g., a first scribe seal side 306A, a second scribe seal side 306B, a third scribe seal side 306C and a fourth scribe seal side 306D, where each scribe seal side separates a side of the device region 302 from a corresponding scribelane portion remaining after the dicing operation. Further, there may not be a POR slot in a PO layer formed over the process wafer from which the semiconductor die 300 is singulated, e.g., the wafer 200 described above. Accordingly, the scribe seal 307 may remain covered by the PO layer in some examples herein.

The semiconductor substrate 301 may have a first cut side 309A, an opposite second cut side 309B, a third cut side 309C and a fourth cut side 309D opposite to the third cut side 309C. A first scribelane portion 308A extends from the scribe seal side 306A to the first cut side 309A, a second scribelane portion 308B extends from the scribe seal side 306B to the second cut side 309B, a third scribelane portion 308C extends from the scribe seal side 306C to the third cut side 309C, and a fourth scribelane portion 308D extends from the scribe seal side 106D to the fourth cut side 109D.

Because the semiconductor die 300 is singulated from a wafer having interleaved scribelanes as described above, only a scribelane portion associated with a bond pad side of the die 300 may include remnants of conductive scribelane structures, e.g., the first scribelane portion 308A containing remnants 310, with the remaining scribelane portions 308B-308D being devoid of remnants from conductive scribelane structures. In the example herein, the circuitry 305 of device 300 includes one or more bond pads 303 provided as part of or otherwise associated with the first circuit portion 304A that is operable as an interface circuit disposed in a low voltage domain. In some arrangements, the second circuit portion 304B may include current sensing circuitry based on Hall effect, which will be set forth in detail further below in reference to some packaging examples where the sensing circuitry may be exposed to electric fields generated by conductors in a high voltage domain.

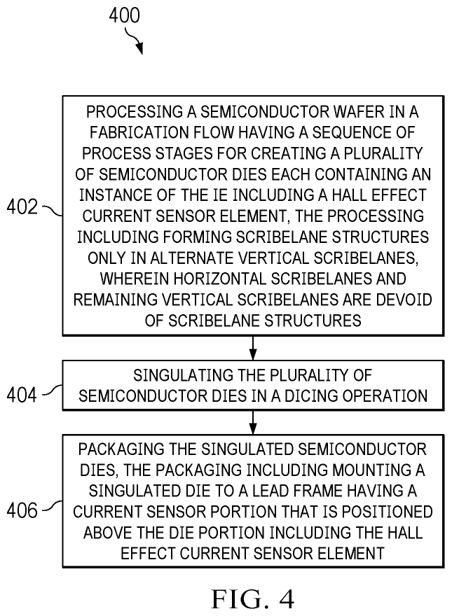

FIG. 4 is a flowchart of a method 400 of fabricating a semiconductor device according to some examples. Method 400 may include processing a semiconductor wafer in a fabrication flow having a sequence of process stages for creating a plurality of semiconductor dies, each containing an instance of the IC, e.g., including a Hall effect current sensor element, as set forth at block 402. In the examples herein, the processing includes forming scribelane structures only in alternate scribelanes extending in one direction, where scribelanes extending in a second direction are devoid of scribelane structures. As set forth above, a first subset of the scribelanes extending in a first direction (e.g., a vertical orientation) may include conductive scribelane structures and a second subset of the scribelanes extending in the first direction and interleaved with the first subset do not contain conductive scribelane structures. At block 404, the plurality of semiconductor dies may be singulated in a dicing operation, which may include mechanical dicing or laser dicing. At block 406, the singulated semiconductor dies may be packaged, where the packaging includes mounting or affixing a singulated die to a lead frame having a current sensor portion that is positioned above the die portion including the Hall effect current sensor element.

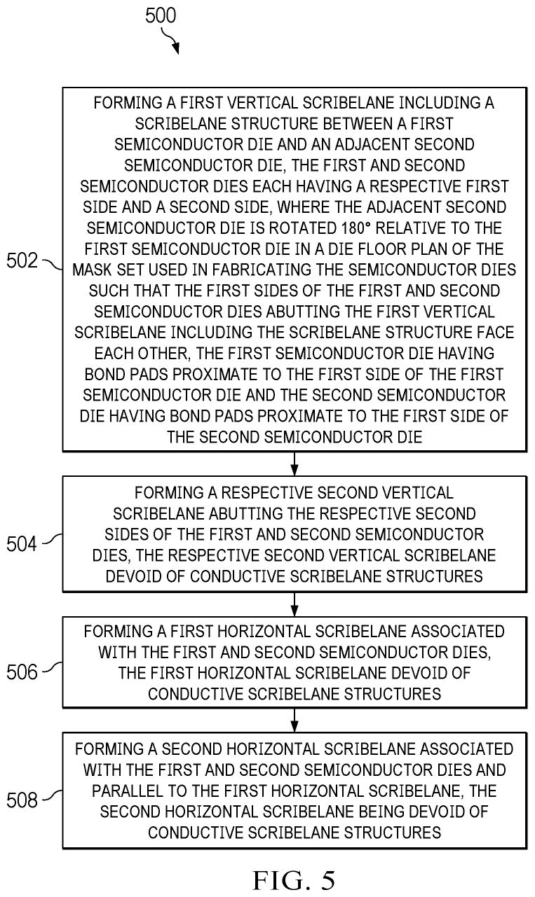

FIG. 5 is a flowchart of a method 500 of fabricating a semiconductor device including additional details according to some examples. At block 502, a first vertical scribelane including a scribelane structure may be formed between a first semiconductor die and an adjacent second semiconductor die, where the first and second semiconductor dies each have a respective first side and a second side. In one example, the adjacent second semiconductor die is rotated 180° relative to the first semiconductor die in a die floor plan of the mask/reticle set (collectively referred to as a “maskset”) used in fabricating the semiconductor dies such that the first sides of the first and second semiconductor dies abutting the first vertical scribelane including the scribelane structure face each other. As previously set forth, the first semiconductor die may be formed with bond pads proximate to the first side of the first semiconductor die and the second semiconductor die may be formed with bond pads proximate to the first side of the second semiconductor die. At block 504, a respective second vertical scribelane abutting the respective second sides of the first and second semiconductor dies is formed, where the respective second vertical scribelane are devoid of conductive scribelane structures, e.g., scribelane structures having metallic components. At block 506, a first horizontal scribelane abutting first horizontal sides of the first and second semiconductor dies is formed, where the first horizontal scribelane is devoid of conductive scribelane structures, e.g., scribelane structures having metallic components. In similar manner, a second horizontal scribelane abutting second horizontal sides of the first and second semiconductor dies and parallel to the first horizontal scribelane is formed, the second horizontal scribelane being devoid of conductive scribelane structures, e.g., scribelane structures having metallic components (block 508).

The foregoing examples of scribelane structure (re)arrangement effectuated by way of die floor plan management may be particularly useful in applications where the devices may be exposed to high electric fields. In some arrangements where integrated semiconductor devices are provided with internal isolation in a device package, semiconductor dies are separated from high voltage signals by an isolation barrier. For example, a semiconductor die with an integral Hall effect element (or simply a Hall element) configured as a current sensor may be mounted to a package substrate, such as a lead frame, by dielectric materials. A high voltage input signal, having a maximum voltage of hundreds of volts, a kilovolt or several kilovolts, may be coupled to the lead frame in some applications, e.g., electric vehicle (EV) charging, automotive traction inverters, servo drivers, etc. A Hall current sensor within the circuitry of the semiconductor die may be configured to output a signal that varies in response to a magnetic field caused by the current flowing in portions of the lead frame, while the semiconductor die remains electrically isolated from the high voltage. The package substrate may include additional leads that are also isolated from the high voltage, which may be configured to provide power, control, and output signals for the semiconductor die. Other types of semiconductor devices requiring electrical isolation may also be mounted in a semiconductor device package using suitable dielectric materials. For example, a pair of semiconductor dies may form a transformer of inductors having coils spaced apart by an isolation dielectric layer, which enables the transmission of power across isolated components without direct connection. In these and other device applications demanding internal isolation, a high voltage input to the semiconductor device package can create a high electric field. Dielectric materials such as die attach materials and mold compound material can fail in the high electric field, causing defects such as arcing, shorts, etc., especially where remnants of conductive metallic components of the scribelane structures may act as localized field concentrators when exposed to electric fields as previously noted. Moreover, high electric field concentrations in a semiconductor device package due to the sharp contours and/or corners of the metallic remnants can lead to localized dielectric breakdown of the materials, forming arcs and unwanted conductive paths within the materials, causing conductive shorts, which can lead to device failures or can cause test failures of otherwise good devices, both in test and in field, thus potentially adding to costs.

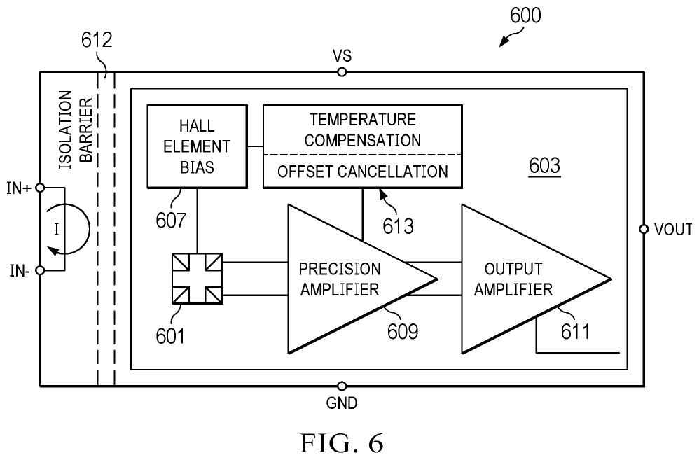

FIG. 6 illustrates in a circuit block diagram of a packaged integrated circuit including a Hall current sensing element that may be fabricated using a die floor plan with scribelane structure (re)arrangement for mitigating high voltage failure risk according to some examples. Depending on application, an IC package 600 may have an input IN+ that is configured as a first node operable to be coupled to an external system (not specifically shown in this Figure) for receiving a signal carrying current (I), e.g., IN+ may be coupled to a high voltage signal or voltage supply, and an output IN− configured as a second node for outputting the current (I). A semiconductor die 603 within the package 600 may include a Hall element 601 (or a pair of Hall elements where differential sensing is implemented). Circuitry configured to control and monitor the Hall element(s) 601 may be provided in semiconductor die 603 including a Hall element bias circuit 607, a temperature compensation and offset cancellation circuit 613, a precision amplifier 609, and an output amplifier 611, as well as internal sensor diagnostics, precision reference circuitry, threshold generator circuitry, etc., which are not specifically shown in this Figure. In operation, the output amplifier 611 drives an output VOUT that corresponds to the magnitude of the current I or which changes with variations in the current I. In operation, a magnetic field component of an electromagnetic field that occurs due to the current I is sensed by the Hall element 601 within semiconductor die 603, and a voltage VOUT corresponding to the magnitude of the magnetic field is output by semiconductor die 603. In an application system, a calibration scheme can be used to determine the value of the current I from the voltage that appears at the output VOUT. An isolation barrier 612 is shown, which may be formed by use of a package substrate with isolated portions to mount the semiconductor die 603 within the electromagnetic field (having the magnetic and electric field components that are orthogonal to each other), but keeping the semiconductor die 603 electrically isolated from the input IN+ and the output IN− where the current I is supplied.

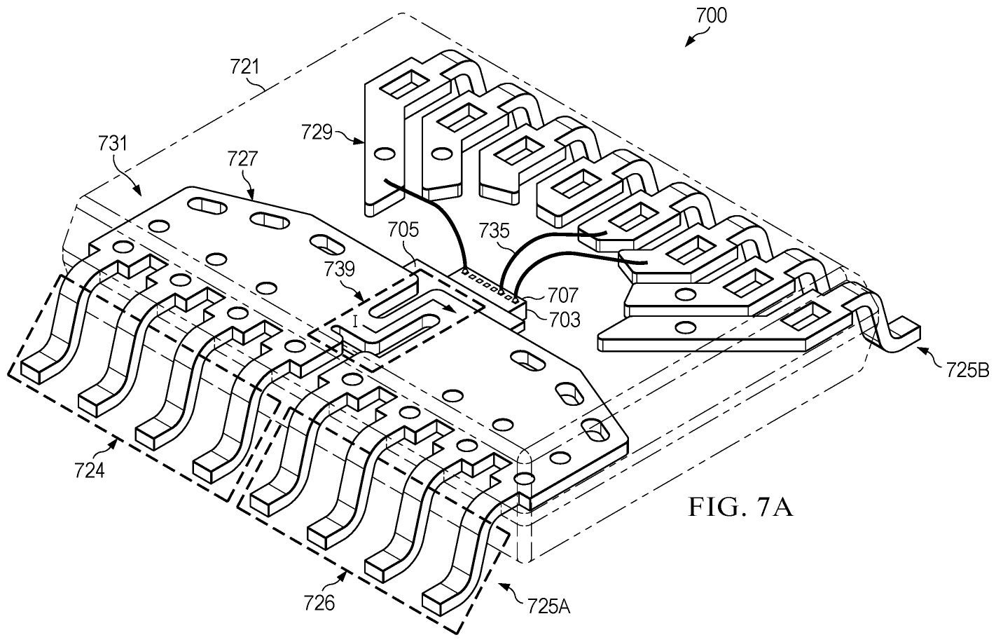

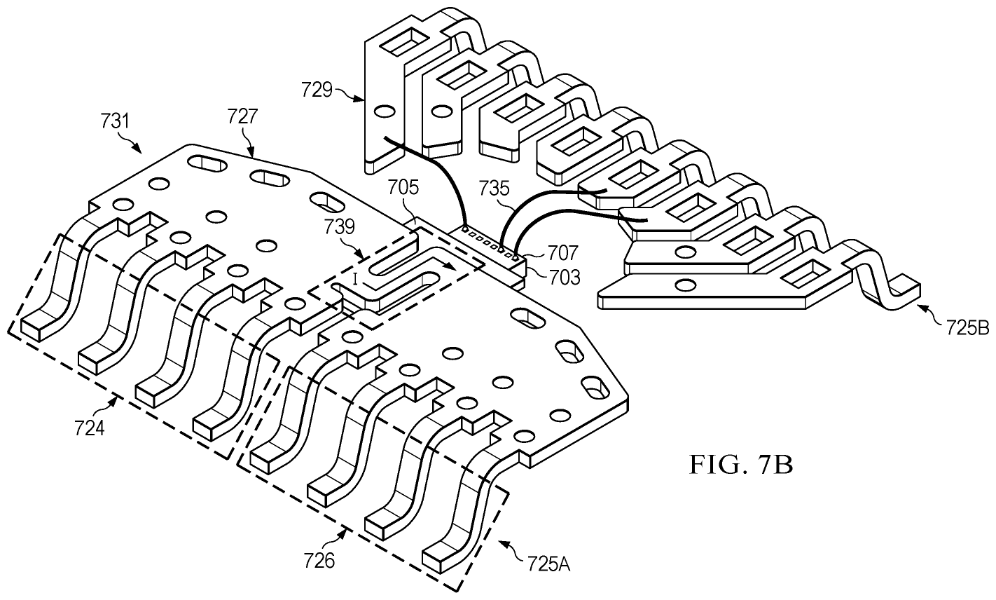

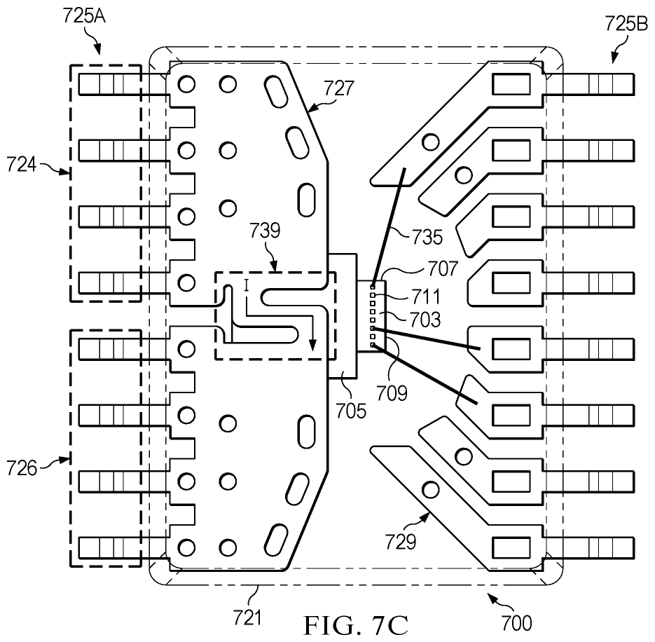

FIG. 7A illustrates, in a partial cutaway view, a three-dimensional (3D) representation of a semiconductor device package 700 for use with a semiconductor die such as die 603 in an arrangement. A package substrate 731, which may comprise a conductive lead frame, may be configured to include a first portion 727 having a first plurality of leads 725A and a second portion 729 having a second plurality of leads 725B, where the first portion 727 and the second portion 729 are spaced apart and electrically isolated from one another. A semiconductor die 703, which may include a Hall element similar to the semiconductor die 603 depicted in FIG. 6, is mounted to a dielectric spacer 705 (e.g., comprising polyimide material), which in turn is mounted to the first portion 727 of the package substrate 731. In this manner, the semiconductor die 703 is proximate to, but not electrically coupled to, the first portion 727 of the package substrate 731. The second portion 729 of the package substrate 731 is electrically coupled to the semiconductor die 703 by electrical connections 735 between the semiconductor die 703 and the leads 725B of the second portion 729. Whereas the electrical connection 735 may comprise bond wires in an example, other connectors such as ribbon bonds, tape bonds, etc., can be used in other arrangements. The semiconductor die 703, the dielectric spacer 705, electrical connections 735, and portions of the package substrate 731 may be encapsulated with or in a mold compound, or body, 721, which forms a package body. The dielectric spacer 705 may include a portion that extends past the first portion 727 of the lead frame, and the semiconductor die 703 has a portion including bond pads that extends past the dielectric spacer 705. In some arrangements, the first plurality of leads 725A may be grouped into two sets 724, 726, where the leads of a respective set may be commonly coupled to a shared node, e.g., an IN+ or IN− node, respectively.

Depending on implementation, the first lead frame portion 727 may be disposed over or under the semiconductor die 703, electrically isolated therefrom by the dielectric spacer 705 and suitable die attach material (not shown) used for mounting. In some arrangements, the package substrate 731 including conductive lead frame portions 727, 729 may be comprised of a conductive metal, including but not limited to copper, gold, Alloy 42, aluminum, stainless steel, steel, and/or alloys thereof. In some examples, a copper lead frame having a thickness between about 0.1 and 0.6 millimeters (mm) may be used. In some arrangements, the conductive lead frame portions 727, 729 may be formed by stamping or etching a sheet of the conductive material to form conductive leads, die pads, solid portions for supporting low resistance conductive paths and/or to add strength, and/or to add divots, holes, openings and slots that form mold compound locks to increase adhesion of mold compound to the lead frame features.

FIG. 7B illustrates features of the lead frame portions 727, 729 without the mold body. In FIG. 7B, the first set or subset of leads 724 coupled to the lead frame portion 727 may be configured to receive a current I at a first node (e.g., IN+). For example, leads 724 may be coupled to a high voltage signal or supply of greater than several hundred volts, a kilovolt, or several kilovolts (kVs), without limitation. Depending on the application, example ranges for the high voltage signal may vary from 300 V to 2 kV and the currents may range from 0 to 200 amperes (A). Relative to the incoming current signal, the second set or subset of leads 726 may be configured for outputting the current I to a second node, e.g., IN− node. The current I received at IN+ node flows through a current sense portion 739 of the first lead frame portion 727, where the current sense portion 729 may comprise a loop, an S-shaped element, etc., that is coupled to the leads 726.

In an example arrangement, the semiconductor die 703 is mounted to the dielectric spacer 705 that is attached to a first side (e.g., a top side or a bottom side) of the first lead frame portion 727 including the current sense portion 739 such that a device region portion of the semiconductor die 703 containing the sensing circuitry, e.g., Hall effect sensor(s) 601 shown in FIG. 6, is under or over the current sense portion 739. Accordingly, the sensing circuitry of the semiconductor die 703 (analogous to the circuit portion 304B of the device 300 described above in detail with reference to FIG. 3) is positioned to be within a magnetic field produced by current I in the current sense portion 739. As noted previously, the dielectric spacer 705 and die attach material(s) that couple the dielectric spacer 705 to the first lead frame portion 727 of the package substrate 731 and die attach material(s) that couple the semiconductor die 703 to the dielectric spacer 705 together form and/or operate as a multilayer/laminated isolator between the semiconductor die 703 and the first lead frame portion 727. The second lead frame portion 729 of the package substrate 731 is electrically coupled to the bond pads, e.g., bond pads 711, disposed on an exposed bond pad side portion 707 of the semiconductor die 703 (e.g., analogous to the bond pad sides 295A of semiconductor dies 202 described above) using the wire bond connections 735. As shown in the examples herein, the connections 735 may be disposed in an electrically conductive relationship with one or more leads 725B that may be configured to facilitate interface functionality between a circuit portion of the semiconductor die 703 and an external circuit or system, generally operable at lower voltages, e.g., on the order tens of volts or less. Whereas the dielectric spacer 705 extends past the first lead frame portion 727, the dielectric spacer 705 does not cover or overlie the exposed bond pad side 707 of the semiconductor die 703. Because the first and second lead frame portions 727 and 729 are spaced part within the mold body 721, and the exposed bond pad side 707 is positioned away from the field-generating current sense portion 739 of the first lead frame portion 727, the risk of lateral discharge relative to the bond pads 711 and/or any remaining conductive scribelane structure portions present in a scribelane portion 709 is expected to be minimal. FIG. 7C depicts a top plan view of the spatial overlay arrangement of the lead frame portion 727, the dielectric spacer 705 and the exposed bond pad side 707 of the semiconductor die 703 in an example arrangement.

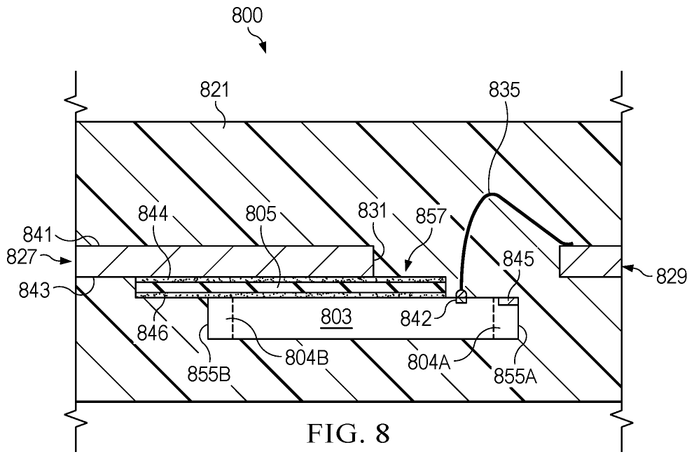

FIG. 8 depicts a partial cross-sectional view of a package 800 including a semiconductor device 803 in an example arrangement of the present disclosure. The package 800 comprises a mold body 821 (analogous to the mold body 721 described above), encasing or encapsulating a first lead frame portion 827 having a first side 841 and an opposite second side 843, and a second lead frame portion 829, analogous to the portions 727, 729 described above. In this example, a dielectric spacer 805 is affixed to the second side 843 of the first lead frame portion 827 using a die attach material or layer 844. A semiconductor die 803 including a first scribelane portion 804A with a first cut side 855A and a second scribelane portion 804B with a second cut side 855B, where the semiconductor die 803 is analogous to the singulated die or device 300 described above, is attached to the dielectric spacer 805 using a die attach material or layer 846. The second lead frame portion 829 may be spaced apart and away from the semiconductor die 803 by a minimum distance in vertical and/or horizontal directions in some arrangements, e.g., about 400 μm to 600 μm. In some additional and/or alternative arrangements, the second lead frame portion 829 may overlie or underlie the semiconductor die 803 having a suitable vertical separation therebetween.

A multilayer isolator structure 857 comprising the dielectric spacer 805 and the die attach layers 844, 846 may therefore be disposed between the first lead frame portion 827 and the semiconductor die 803. A suitable electrical connector 835 is provided for coupling a bond pad 842 of the semiconductor die 803, which is proximate to the first scribelane portion 804A, to the second lead frame portion 829 at a suitable location. In the example herein, the first scribelane portion 804A may include one or more conductive remnants 845 of scribelane structures that have been diced through in singulating the semiconductor die 803, whereas the second scribelane portion 804B may be devoid of such conductive remnants, thus potentially mitigating the risk of undesirable electrical discharge conditions as described above. In some examples, a vertical side 831 of the first lead frame portion 827 extending over the semiconductor die 803 (e.g., over the second cut side 855B and toward the first cut side 855A) may comprise a perpendicular wall relative to the multilayer isolator 857 as illustrated in FIG. 8. In some examples, the vertical side 831 may have an angled profile, thereby providing a chamfered edge at the multilayer isolator 857, which may help reduce lateral discharging.

In examples herein, various types of leaded packages may be used in arrangements similar to the arrangement set forth above. In an example leaded package, the leads may extend away from the package body and may be shaped to form a portion for soldering to a printed circuit board (PCB) or other suitable substrate. A dual in-line package (DIP) may be used in some examples. A thin DIP package arranged with leads for surface mounting can be referred to as a small outline integrated circuit or “SOIC” package, which may be used in some examples. SOIC packages of various types can be used in example arrangements, including narrow body, wide body, and double wide or wider body SOIC packages. Single sided packages such as leaded center bond packages may also be used in additional and/or alternative arrangements. Still further, some example arrangements may include what are referred to as “no-lead” packages, where the package terminals are coextensive with the molded package body, e.g., including quad flat no-lead (QFN) and small-outline no-lead (SON) packages.

Various types of dielectric spacer materials and die attach materials may be used in the fabrication of a multilayer isolator such as the isolator 857 configured for providing internal isolation in a package as previously noted. Additional details regarding Hall sensor packages, isolator materials and chamfering of isolator edges may be found in U.S. Pat. Nos. 11,621,215 and 11,322,433, each of which is incorporated by reference in its entirety for all purposes. Additional details regarding test pad structures, etc. operable as example scribelane structures may be found in U.S. Patent Application Publication No. 2023/0282595, which is incorporated by reference in its entirety for all purposes.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers and/or structures set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate having a first cut side and an opposite second cut side;
a circuit formed in or over the semiconductor substrate between the first and second cut sides; and
a first scribelane portion between the circuit and the first cut side and a second scribelane portion between the circuit and the second cut side, the first scribelane portion including conductive scribelane structures, and the second scribelane portion being devoid of conductive scribelane structures.

2. The semiconductor device as recited in claim 1, wherein the semiconductor substrate has a third cut side and a fourth cut side opposite to the third cut side, a third scribelane portion between the third cut side and the circuit, and a fourth scribelane portion between the fourth cut side and the circuit, the third and fourth scribelane portions devoid of conductive scribelane structures.

3. The semiconductor device as recited in claim 1, wherein the circuit comprises a sensor circuit portion and an interface circuit portion.

4. The semiconductor device as recited in claim 3, wherein the sensor circuit portion is configured to operate in an electric field from a high voltage conductor.

5. The semiconductor device as recited in claim 3, wherein the sensor circuit portion includes a Hall effect current sensor.

6. The semiconductor device as recited in claim 1, wherein the first scribelane portion is between a plurality of bond pads and the first cut side.

7. The semiconductor device as recited in claim 1, further comprising a scribe seal surrounding the circuit, the scribe seal covered by a protective overcoat.

8. A method of fabricating an integrated circuit (IC), the method comprising:
processing a semiconductor wafer in a fabrication flow having a sequence of process stages for creating a plurality of semiconductor dies each containing an instance of the IC, the semiconductor wafer providing a substrate for the IC, the processing including forming scribelanes extending in a first direction, a first subset of the scribelanes including conductive scribelane structures and a second subset of the scribelanes interleaved with the first subset and being devoid of conductive scribelane structures; and
singulating the plurality of semiconductor dies in a dicing operation.

9. The method as recited in claim 8, wherein the scribelanes are first scribelanes, and further comprising forming second scribelanes extending in a different second direction, wherein the second scribelanes are devoid of conductive scribelane structures.

10. The method as recited in claim 8, wherein:
the semiconductor dies have a first side including bond pads and an opposing second side having no bond pads;
the scribelanes of the first subset are located between corresponding first and second adjacent columns of the semiconductor dies; and
the first sides of the semiconductor dies of the first column face the first sides of semiconductors dies of the second column.

11. The method as recited in claim 8, wherein:
the scribelanes of the first subset are located between corresponding first and second adjacent columns of the semiconductor dies; and
the semiconductor dies of the first column are identical to and rotated 180° with respect to the semiconductors dies of the second column.

12. The method as recited in claim 8, wherein a scribelane devoid of the conductive scribelane structures is formed between first and second adjacent columns of semiconductor dies, the first column containing semiconductor dies having non-bond-pad sides that face non-bond-pad sides of semiconductor dies of the second column.

13. The method as recited in claim 8, wherein the IC contains:
a sensor circuit portion that extends from a first scribe seal side to an opposing second scribe seal side, and from a third scribe seal side toward an opposing fourth scribe seal side, the sensor circuit portion having no exposed conductive features; and
an interface circuit portion that extends from the first scribe seal side to the second scribe seal side, and from the fourth scribe seal side toward the third scribe seal side, the interface circuit portion having exposed metallic bond pads.

14. The method as recited in claim 13, wherein the sensor circuit portion includes a Hall effect current sensor.

15. The method as recited in claim 13, wherein the scribe seal sides are covered by a protective overcoat.

16. A packaged integrated circuit (IC), comprising:
first package leads on a first side of a device package and second package leads on an opposite second side of the device package;
a semiconductor die having a first cut side and an opposite second cut side;
a circuit located between the first and second cut sides, the circuit including a first circuit portion and a second circuit portion, the semiconductor die located between the first package leads and the second package leads;
a first scribelane portion between the circuit and the first cut side and a second scribelane portion between the circuit and the second cut side, the first scribelane portion including conductive scribelane structures, and the second scribelane portion being devoid of conductive scribelane structures;
a lead frame portion over or under the semiconductor die, the lead frame portion extending over the second cut side toward the first cut side and ending over the second circuit portion;
bond pads between the first circuit portion and the first cut side; and
bond wires connected between the bond pads and the second package leads.

17. The packaged IC as recited in claim 16, further comprising a current loop in the lead frame portion.

18. The packaged IC as recited in claim 16, wherein the semiconductor die is devoid of bond pads under or over the lead frame portion.

19. The packaged IC as recited in claim 16, wherein the lead frame portion is configured to have a DC voltage of at least 300 V with respect to the semiconductor die.

20. The packaged IC as recited in claim 16, wherein the second circuit portion includes a Hall effect current sensor.

21. The packaged IC as recited in claim 16, wherein the semiconductor die has a third cut side and a fourth cut side opposite to the third cut side, a third scribelane portion between the third cut side and the circuit, and a fourth scribelane portion between the fourth cut side and the circuit, the third and fourth scribelane portions devoid of conductive scribelane structures.
